(19) United States
(12) Patent Application Publication
(10) Pub. No.: US 2014/0054638 A1
(43) Pub. Date: Feb. 27, 2014

(54) LIGHT EMITTING DEVICES HAVING SHIELDED SILICON SUBSTRATES

(71) Applicant: Toshiba Techno Center, Inc., Tokyo (JP)

(72) Inventors: Steven D. Lester, Livermore, CA (US); Long Yang, Livermore, CA (US); Chao-Kun Lin, Livermore, CA (US)

(73) Assignee: TOSHIBA TECHNO CENTER, INC., Tokyo (JP)

(21) Appl. No.: 14/114,312

(22) PCT Filed: Mar. 11, 2013
(86) PCT No.: PCT/US2013/030281

§ 371 Date: Oct. 28, 2013

Related U.S. Application Data
(60) Provisional application No. 61/622,710, filed on Apr. 11, 2012.
(60) Provisional application No. 61/661,982, filed on Jun. 20, 2012.

(51) Int. Cl. H01L 33/60

(52) U.S. Cl. CPC H01L 33/60
USPC 257/98; 438/27

(57) ABSTRACT

Light emitting devices comprise a light emitting component, such as a GaN LED having active material layers supported by a Silicon substrate, which can be a growth substrate, or attached. Phosphor(s) can be disposed relative to the light emitting component to absorb a primary emission, and produce a secondary emission that can be relatively tuned or selected so that their combination produces light of a desired spectrum, such as light appearing white. The Silicon substrate has exposed sidewalls, which can be angled, with respect to planar surfaces of the substrate, and a light reflecting material, such as a diffusely reflective material coats the sidewalls. The reflective material can be opaque to the primary and secondary emissions. If other exposed portions of the Silicon substrate exist and are exposed to primary or secondary light, these other exposed portions can be coated with such light reflecting material.

### BACKGROUND

1. Field

The following relates to light emitting components, such as Light Emitting Diode devices and assemblies, and in one particular aspect, to devices with Gallium Nitride type active regions that are supported from a Silicon substrate.

2. Related Art

Conventionally, Gallium Nitride active regions are typically formed on Sapphire substrates or on Silicon Carbide substrates. Gallium Nitride active regions can be tuned to output different frequencies of light, and for example, can be tuned to emit Blue light (e.g., 460 nm). A source of blue light can be used as a photon source to stimulate one or more phosphors that generate other frequencies of light. The emissions from the LED and the phosphor(s) can appear, upon mixing, as white light, such as cool white light, or warm white light.

Improved light emitting device technology may allow higher efficiency, lower operating costs, or lower production costs, for example.

### SUMMARY

In an example, a light emitting device comprises a light emitting component with a Silicon substrate. The Silicon substrate includes a top surface, a bottom surface and side walls. In an example, a light emitting region is formed on the top surface, and may be co-extensive with the substrate, or may not entirely cover the substrate. The substrate may be the growth substrate or may have been attached, and the growth substrate removed.

A light reflecting layer is formed on at least a portion of the side walls of the Silicon substrate; and may entirely cover the sidewalls. The reflecting layer may also cover an exposed top surface of the substrate. A material used to form the reflecting layer can be metallic, and can be formed by sputtering or evaporation; such as sputtering of Aluminum. The coating can be a matrix containing reflecting particles, such as an oxide of Titanium.

A phosphor is formed over at least a portion of the light emitting component. The light emitting component, in an example, comprises a Nitride compound semiconductor represented by the formula: InᵢGaⱼAlₖN where 0≦i, 0≦j, 0≦k and i+j+k=1.

The phosphor is capable of absorbing a part of light emitted by the light emitting component, emitting light of a wavelength different from that of the absorbed light, and reflecting a part of the light emitted by the light emitting component.

The light reflecting layer prevents one or more of a portion of the light emitted by the light emitting component and reflected by the phosphor, and a portion of the light emitted by the phosphor from being absorbed by the portion of the side walls of the substrate covered by the light reflecting layer.

In one approach, the light reflecting layer comprises Silicone and an oxide of Titanium. The light emitting device may be mounted in a holder. The phosphor may include one or more of a Yttrium Aluminum Garnet phosphor and a Lutetium Aluminum Garnet phosphor activated with Cerium. The phosphor may contain any one or more of Se, La, Gd and Sm in partial substitution for Yttrium, and any one or more of Ga and In, in partial substitution for Aluminum.

In another aspect, a method of fabricating a light emitting device comprises forming a light emitting component on a Silicon substrate. The Silicon substrate comprises a top surface, a bottom surface and side walls. A phosphor, such as a phosphor coating, is formed over at least a portion of the light emitting component. The phosphor is capable of: absorbing a part of light emitted by the light emitting component, emitting light of wavelength different from that of the absorbed light, reflecting a part of the emitted light by the light emitting component.

A light reflecting layer is formed on at least a portion of the side walls of the Silicon substrate, the light reflecting layer preventing at least 1) a portion of the light emitted by the light emitting component and reflected by the phosphor, and 2) a portion of the light emitted by the phosphor, from being absorbed by the portion of the side walls of the substrate covered by the light reflecting layer. In one example, the Silicon substrate used for formation is removed, and a different Silicon substrate is adhered to the light emitting portion.

### BRIEF DESCRIPTION OF THE DRAWINGS

Various features and aspects of the disclosure will become more apparent from the following detailed description, which is to be read in conjunction with the accompanying drawings, in which:

FIGS. 1-5 schematically depict an example construction of light emitting component layers on a Silicon substrate, which can be diced to produce light emitting components;

FIG. 6 depicts an example set of process steps for producing wafer containing GaN light emitting components on a Silicon wafer substrate;

FIG. 7A depicts a top view of a wafer from which light emitting components can be singulated;

FIG. 7B depicts a top view portion of the wafer from FIG. 6A having a light emitting component with scribe lanes;

FIG. 8 depicts a cross section of a light emitting component shown in top view in FIG. 6B, in which a Silicon substrate is generally co-extensive with other layers of the component;

FIG. 9 depicts another example of a cross section of a light emitting component shown in top view in FIG. 7B, in which a Silicon substrate is larger than other layers of the component;

FIG. 10 depicts an example applied reflective layer to the component of FIG. 8;

FIG. 11 depicts an example applied reflective layer to the component of FIG. 9;

FIG. 12 depicts a top view of light emitting components attached to a sub-mount;

FIGS. 13-15 depict example masks that can be used to mask off parts of the light emitting components shown in FIG. 12;

FIG. 16 depicts a carrier bonded to the wafer of FIG. 7A;

FIG. 17 depicts aspects of scribing or otherwise cutting the wafer to expose sidewalls of the Silicon substrate for the light emitting components;

FIG. 18 depicts masking and depositing a reflecting coating on sidewalls of substrates of the components;

FIG. 19 depicts top views of resulting light emitting components;

FIG. 20 depicts a cross-section of a light emitting component of FIG. 18;

FIGS. 21A, 21B and 22 depict example approaches to singulating light emitting components and providing a reflecting layer according to the disclosure; and

FIG. 23 depicts another example approach to singulating light emitting components and providing a reflecting layer according to the disclosure;

FIG. 24 depicts an example phosphor-containing encapsulation of a light emitting component;

FIG. 25 depicts an example approach to mounting light emitting components according to the disclosure and providing a phosphor layer over the mounted light emitting components;

FIG. 26 depicts an example of potting an array of mounting light emitting components according to the disclosure in a phosphor contain resin;

FIG. 27 depicts an example of a conformal phosphor coating over mounted light emitting components according to the disclosure;

FIG. 28 depicts a cross-section of a silicon substrate having processed LED devices disposed on a stretch tape for singulation;

FIG. 29 depicts deposition of an etch mask on the silicon substrate depicted in cross-section in FIG. 28;

FIG. 30 depicts, in cross-section, a directional etch that produces angled sidewalls between the LED devices;

FIG. 31 depicts deposition of a coating on the exposed surface of the substrate, after etch processing;

FIGS. 32A and 32B respectively depict an insulating coating and a insulating coating followed by a metal coating for the coating depicted in FIG. 31; and

FIG. 33 depicts that the LED devices can thereafter be separated, such as by stretching the tape.

### DETAILED DESCRIPTION

In an example, light emitting components according to the disclosure include light emitting diodes (LEDs). For ease of description, the term LED for exemplary disclosures; however, it should be understood that light emitting components according to the disclosure are not required to include a diode. One particular example in the present disclosure is a light emitting component based on a Gallium Nitride active region, which is formed on or supported from a Silicon (Si) substrate. Such a light emitting component can include a GaN LED. Using Silicon as a substrate provides comparative cost advantages, because Silicon wafers are less expensive than Sapphire substrates. Also, GaN on Si may be scalable to larger wafer sizes, such as 6, 8, 12, or 14 inch diameter wafers; by contrast, Sapphire substrates are often 2 or 4 inches in diameter. Thus, an average cost per useful light output for a GaN on Si light emitting component is expected to be less than a variety of other light sources.

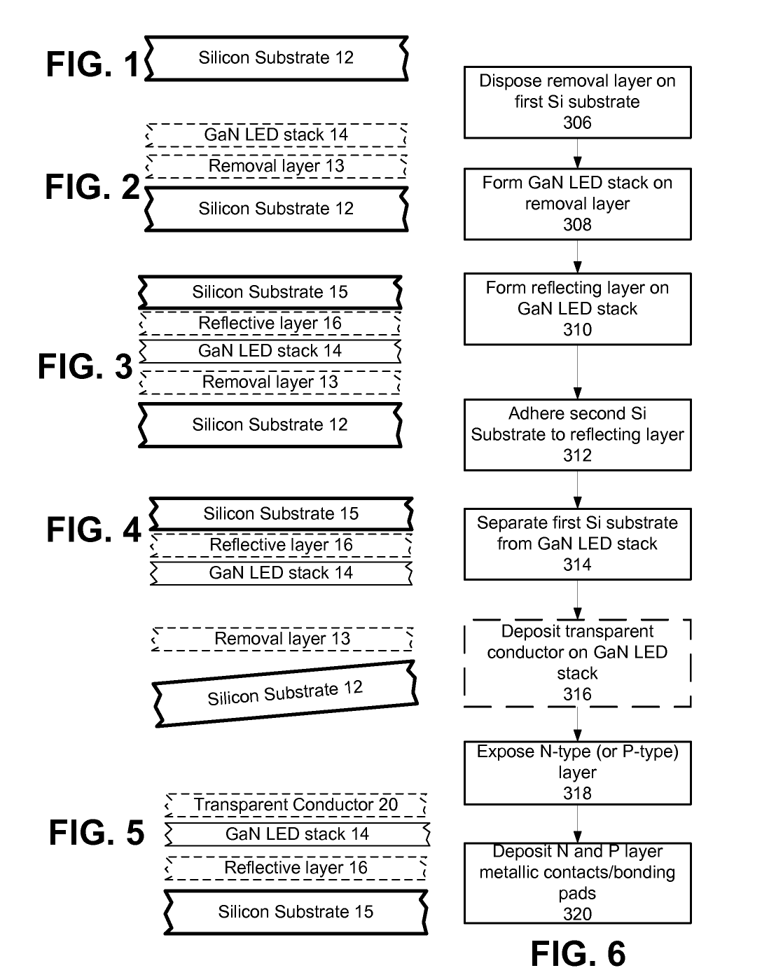

FIGS. 1-5 depict an abbreviated example of a process that can be performed to produce a GaN on Silicon light emitting component.

In FIG. 1, a Silicon substrate 12 is depicted, which can be an 8 inch wafer, for example. FIG. 2 depicts that a removal layer 13 is disposed between substrate 12 and a GaN LED stack 14.

In one example, the GaN LED stack 14 is a layered semiconductor structure comprising Gallium Nitride-based semiconductor layers. The stack 14 can include a buffer layer and a Silicon-doped GaN layer on the buffer layer. The stack 14 can include some or all of the following: a superlattice structure comprising layers of Silicon-doped GaN and/or InGaN formed on the buffer layer, an active region, an undoped InAlGaN layer, another superlattice, an AlGaN layer doped with a p-type impurity, and a contact layer also doped with a p-type impurity. In some approaches, a second Silicon doped GaN layer may be disposed between the GaN layer and the superlattice. The buffer layer may be n-type AlGaN and may be doped with Si. The GaN layer upon the buffer layer also may be doped with Si.

The active region of GaN LED stack 14 may comprise a single or multi-quantum well structure, and be of a single or double heterojunction type. A multi-quantum well structure can include multiple InGaN quantum well layers separated by barrier layers. Barrier layers may be formed to contain Indium. In some approaches, the Indium doping is lighter in barrier layers than in quantum well layers, resulting in a higher bandgap for the barrier layers. Barrier layers may have a Silicon doping. In one example, a peak energy of light emission occurs between 420 and 490 nm, and can be occur at around 450 nm or 460 nm, for example.

Barrier layers also may contain Aluminum. Such barrier layers may have a crystalline structure that matches more closely to the quantum well layers, thereby allowing improved crystalline quality in the quantum well layers, which can increase the luminescent efficiency of the device. Indium content in the quantum well(s) can be adjusted to tune wavelengths of the emitted light.

Considering FIG. 2, removal layer 13 can be a layer of a material that has a relatively low melting or softening temperature.

In FIG. 3, a reflective layer 16 is disposed on GaN LED stack 14, and a second Silicon substrate 15 can be disposed on reflective layer 16. FIG. 4 depicts that GaN LED stack 14 can be separated from Silicon substrate 12 at removal layer 13. FIG. 5 depicts that a transparent conductor layer 20, such as Indium Tin Oxide (ITO) can be disposed on GaN LED stack 14. The processed wafer of FIG. 5 can be used in further processing steps, described below.

FIG. 6 depicts a process flow, for a top emitter LED, generally following the depicted flow of FIGS. 1-5. FIG. 6 depicts that at 306, a removal layer can be disposed on a Si substrate (growth substrate), and at 308, a GaN LED stack can be formed on the removal layer. At 310, a reflecting layer can be formed on the GaN LED stack. At 312, a second Si substrate can be adhered to the reflecting layer (i.e., opposite the growth substrate). At 314, the growth substrate can be separated. At 316, a transparent conductor layer can be formed on the now-exposed GaN LED stack.

Additionally, at 318, an N-type layer in the GaN LED stack 14 can be exposed, and at 320, N and P layer metallic contacts or bonding pads can be disposed on respective surfaces. Examples of cross-sections of such structures are depicted below in FIG. 8, for example.

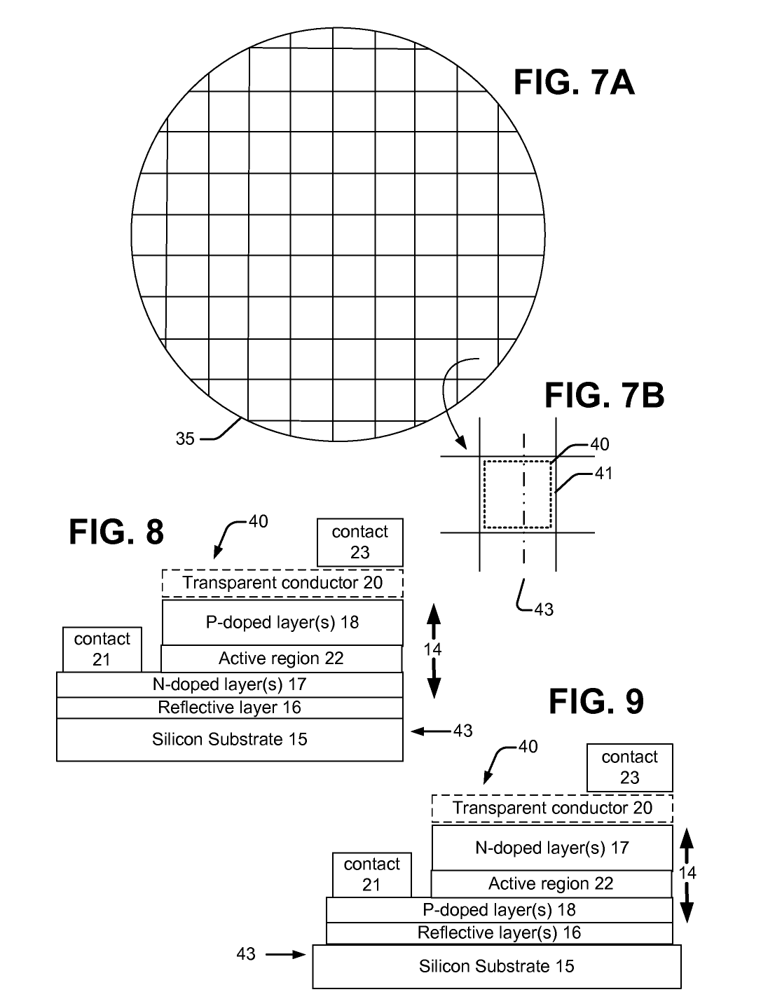

FIG. 7A depicts a wafer 35 and FIG. 7B depicts a chip 40, with scribe lanes 41 around the chip. A cross section mark 43 indicates a cross section that will be illustrated in FIG. 8 and FIG. 9.

FIG. 8 depicts a first example construction of chip 40 at cross section 43, which generally follows a traditional model having the P-doped areas of the LED being exposed for light emission, and a portion of the P regions removed to expose an N-type material for contact. FIG. 8 also depicts a substrate 15 being generally congruent with the layers formed on substrate 15 (by contrast with FIG. 9 which depicts that substrate 15 is larger than the layers formed on it). FIG. 8 and FIG. 9 are provided to show a context in which disclosed aspects may be practiced; rather than a complete disclosure concerning how to build the devices in their entireties. As such, various aspects of the devices are described in summary. In particular, GaN stack 14, which can contain a variety of complex structures, such as a multiple-quantum active region 22, other superlattices, and buffer layers, is not described in detail.

Silicon substrate 15 supports reflective layer 16, over which is disposed GaN LED stack 14. An N-contact 21 makes ohmic contact with an N-doped layer(s) 17 of GaN LED stack 14. Such N-doped layer 17 can be exposed by one or more chemical wet or dry etches, reactive ion etching, and so on. A P contact 23 makes ohmic contact with transparent conductor 20, which in turn contacts a P-doped layer(s) 18. An active region 22 is disposed between the depicted P and N doped layer(s) 18 and 17.

FIG. 9 depicts a layer arrangement in which N-doped layer(s) 17 and P-doped layer(s) are in the relative arrangement depicted, which is opposite that of FIG. 8. Also, in FIG. 8, Silicon substrate 15 is roughly co-extensive with the other layers depicted, while in FIG. 9, Silicon substrate extends beyond the boundaries of the other depicted layers. In both FIG. 8 and FIG. 9, N contact 21 and P contact 23 can be formed prior to singulation. Some embodiments may dispense with transparent conductor 20; for example, in FIG. 9, transparent conductor 20 may be omitted if the layers contacted are sufficiently conductive without its use. A variety of layers in FIGS. 8 and 9 have been omitted or abstracted for the sake of clearly depicting certain aspects of the reflective coatings, and their relationships to the sidewalls of the substrates. For example, the complicated layer structure in GaN stack 14 is not detailed.

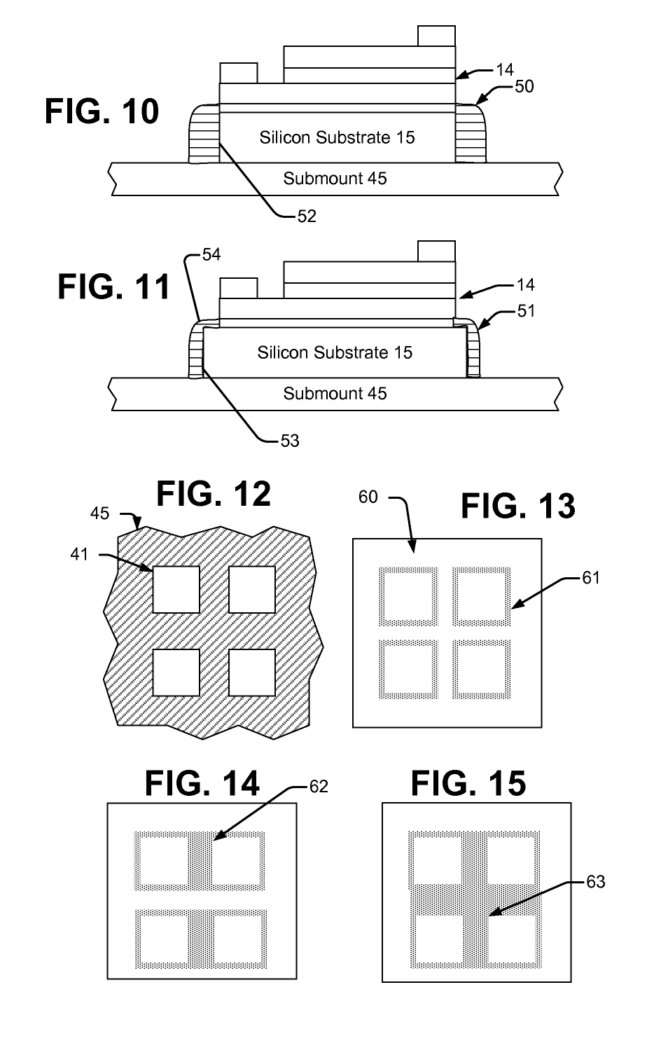

FIG. 10 depicts, in cross-section, a reflective layer 50 disposed to cover sidewalls 52 of Silicon substrate 15 of chip 40 mounted on submount 45. Reflective layer 50 can cover substantially all of the exposed sidewalls of Silicon substrate 15.

FIG. 11 depicts the exposed portions 53 of substrate 15 being covered by a reflective layer 51. Reflective layer 51 in this example, wraps over exposed top surface portions of substrate 15. As will be explained below, reflective layers 50 and 51 can be disposed according to a variety of processes and approaches. In some approaches, reflective layers 50 and 51 can be conformal layers provided during a deposition step. Example approaches are described in more detail below. In one embodiment the reflective layer 51, which wraps over the exposed top surface of the portion of the substrate 15, has a thickness on the top portion of the substrate 15 that is equal to or less than the thickness of the reflective layer 16. The reflective layer 51 on the side portion of the substrate 15 can also have a thickness that is equal to, less than, or more than the thickness of the reflective layer 51 on the top portion of the substrate 15.

In some embodiments, the thickness of the reflective layer 51 can be uniform along the sidewalls. In other embodiments, the thickness of the reflective layer 51 can vary along the sidewalls. For example, the thickness of the reflective layer 51 can be a gradient where it is thicker at the bottom and thinner at the top of the sidewalls. The coating is substantially thick enough to prevent penetration of light into the silicon substrate. The thickness of reflective layer 51 can be thickest at a middle depth point of the sidewalls, and thin towards a top and bottom surface. Substrate in this disclosure can have a perimeter generally in the shape of a polygon, with shapes such as triangles, squares, rectangles, parallograms, trapezoids, hexagons, and so on. A single light emitting component can be formed on a single substrate portion in one example; in other examples, multiple light emitting components can be formed on a single substrate.

In some examples, some parts of a sidewall or some sidewalls of some substrates may not be exposed to reflected light. For example, a sidewall can abut another substrate, or a wall of a package. In such cases, that sidewall or portion thereof, may be uncoated with reflecting material. As such, the parts of sidewalls, the sidewalls themselves, or both that are coated in any particular application can account for the intended packaging.

FIG. 12 depicts a part of submount 45, and a set of chips, including chip 41, mounted to submount 45. FIG. 12 depicts a mask 60 that can be used to shield parts of the chips mounted to submount 45 in order to confine deposition of reflective materials. For example, outline 61 allows deposition of reflective material within the shaded area. FIGS. 14 and 15 depict other examples of masks 62 and 63, respectively, which can be used during deposition of reflective material. Thus, FIGS. 12-15 shows an approach where a wafer is singulated into light emitting components, one or more of the components can be mounted, and then a reflective material can be applied to cover sidewalls of the light emitting components.

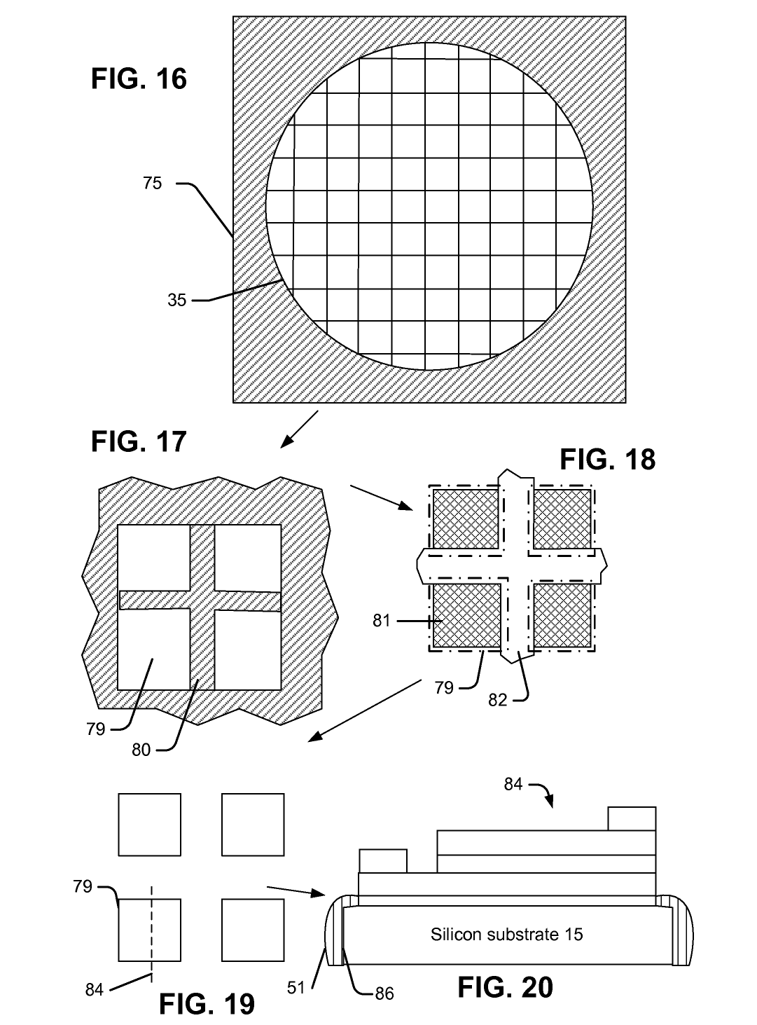

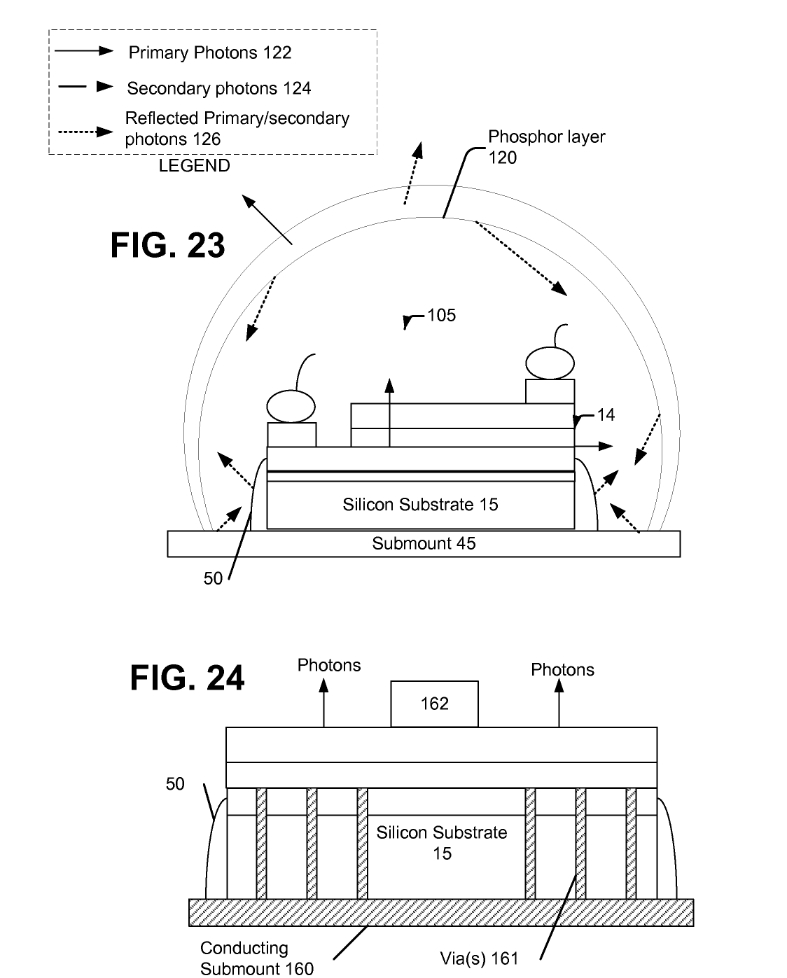

FIGS. 16-20 depict an approach where wafer 35 is mounted to a carrier 75, singulated, but not separated from carrier 75 until after a reflective coating material is deposited on the sidewalls of the light emitting components. FIG. 17 depicts an exploded view of a portion of wafer 35, with a chip 79 (a light emitting component) specifically identified. A scribe pattern 80 is shown to separate light emitting components from each other. FIG. 18 shows an outline of chip 79. Masked region 81 overlies a central portion of chip 79, exposing sidewalls of chip 79. A pattern 82 of reflective material deposition is applied over the mask, which is subsequently removed. As depicted in FIG. 19, the light emitting components are subsequently removed from carrier 75. A cross-section mark 84 is depicted, for use in FIG. 23.

FIG. 20 depicts an example cross section, with reflective coating 51 deposited on sidewalls of Silicon substrate 15.

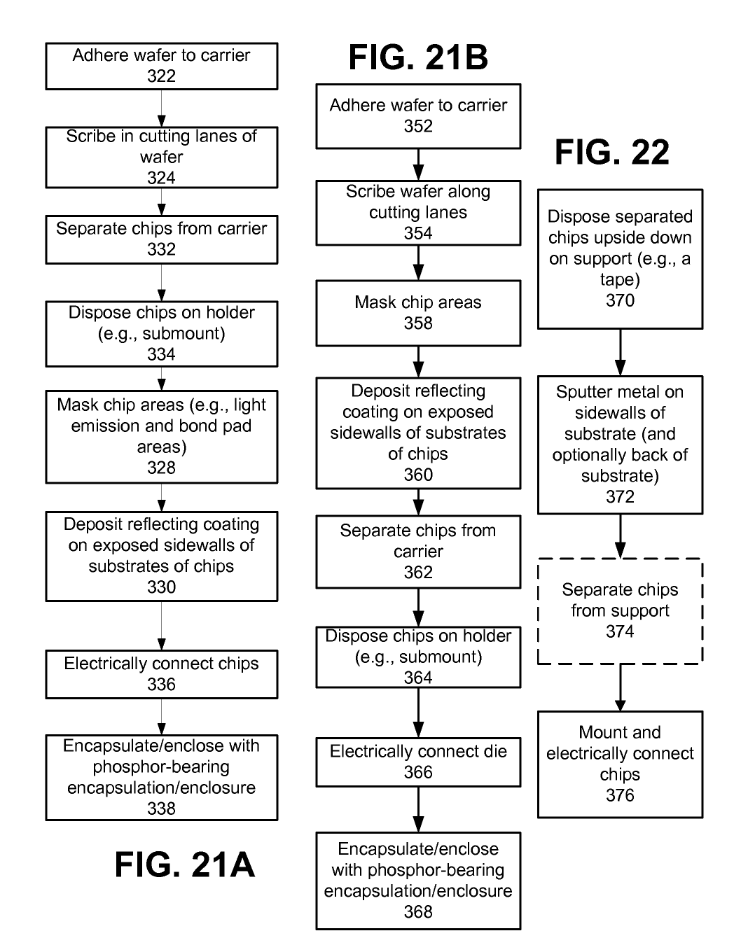

FIG. 21 depicts example processes resulting in singulated light emitting components having sidewalls coated with a light reflecting coating, and generally in accordance with FIGS. 10-15. In FIG. 21, at 322, a wafer is adhered to a carrier (see above figures for examples). At 324, scribing is conducted in cutting lanes provided on the wafer between light emitting components formed thereon, resulting in physical separation of the chips from each other, although adhered to the carrier.

At 332, the chips are separated from the carrier. At 334, the chips are disposed on a holder, such as a submount, depicted above. At 328, areas of the chips are masked, such as bond pad areas, and areas where light is to be emitted. At 330, a reflective coating is deposited on exposed sidewalls of the substrates of the chips.

The reflective coating can be deposited using various techniques including but not limited to spraying, brushing, screen printing, as is explained in further detail below, as well as chemical vapor deposition, plating, evaporation, physical vapor deposition, etc. Further, the reflective coating can be deposited to be conformal to the sidewalls of the substrate and to any top portions of the substrate that the reflective layer may cover. The reflective layer can also be deposited to cover all of the sidewalls or in some embodiments only a portion of the sidewalls. The thickness of the reflective coating can range from several nanometers to many microns. In some embodiments, the thickness of the reflective layer can be uniform along the sidewalls. In other embodiments, the thickness of the reflective layer can vary along the sidewalls. For example, the thickness of the reflective layer can be a gradient where it is thicker at the bottom and thinner at the top of the sidewalls A variety of other examples of reflecting coatings and substrate configurations are within the scope of embodiments, such as the examples disclosed above.

At 336, the chips are electrically connected, such as through wire bonding, or another procedure appropriate for the type of electrical contact to be made (here, electrically connected does not mean connected to a source of potential, for example, but rather that a mechanism to supply such potential to the chips is completed). At 338, a phosphor containing encapsulation or enclosure is provided so that at least some of the light emitted from the mounted chip(s) hits the phosphor and causes secondary emission from the phosphor (explained in more detail below).

FIG. 21B depicts a process generally in accordance with FIGS. 17-20. In particular, FIG. 22 depicts, at 352 that a wafer is adhered to a carrier. In one example, the wafer is adhered with the LED chips exposed (“facing up”). At 354, the wafer is scribed along cutting lanes to singulate chips in the wafer. At 358, portions of the chip are masked which should not have reflective coating. Some implementations may mask before scribing. At 360, a reflective coating is deposited on exposed sidewalls of the substrates of the chips.

FIG. 22 depicts a further variation in which the coating is formed of a reflective metallic material. For example, the reflective coating can contain a metal such as aluminum, gold, platinum, chromium, rhemium, or a combination thereof. The reflective coating can be formed as multiple layers; for example, where a metal reflective layer is used, an underlying insulator layer may be first disposed on the substrate, and then the metal formed on the insulator.

In FIG. 22, following separation of chips (e.g., after singulation), such as at 332 of FIG. 21A, the separated chips are disposed, at 370, upside down on a tape. At 372, a metal is sputtered or evaporated on the exposed sidewalls of the substrates upside down chips. The backs of the substrates can be coated. In one example, 300-600 nanometers of aluminum are sputtered or evaporated onto the sidewalls of the silicon substrate. At 374, the chips can be separated from the support and at 376, they can be electrically connected, packaged otherwise used.

The reflective coating can be deposited using various techniques including but not limited to spraying, brushing, screen printing, as is explained in further detail below, as well as chemical vapor deposition, plating, evaporation, physical vapor deposition, etc. Further, the reflective coating can be deposited to be conformal to the sidewalls of the substrate and to any top portions of the substrate that the reflective layer may cover. The reflective layer can also be deposited to cover all of the sidewalls or in some embodiments only a portion of the sidewalls. The thickness of the reflective coating can range from several angstroms to many nanometers. In some embodiments, the thickness of the reflective layer can be uniform along the sidewalls. In other embodiments, the thickness of the reflective layer can vary along the sidewalls. For example, the thickness of the reflective layer can be a gradient where it is thicker at the bottom and thinner at the top of the sidewalls A variety of other examples of reflecting coatings and substrate configurations are within the scope of embodiments, such as the examples disclosed above. At 362, the chips are separated from the carrier.

At 364, chips are disposed on a holder, such as a submount. At 366, the chips mounted in the holder are connected so that a source of electrical potential can be applied during operation. At 368, the chips are encapsulated, enclosed, or otherwise provided with a phosphor bearing layer or enclosure, such as according to the examples disclosed above. It should be understood, with respect to the example processes of FIG. 21 and FIG. 22 that chips extracted from any particular wafer do not need to be mounted or used immediately in a package, or that chips extracted from one wafer need to be used together. Rather, the chips can be separated, stored, or further processed, split up, binned, and any other process to be undertaken.

The example processes are illustrative and not limiting of approaching that can be taken to result in chips having substrate sidewalls coating according to the disclosure. For example, any suitable approach to singulation may be taken, a carrier may or may not be used, and a process for providing the coating itself can vary.

FIG. 23 depicts a schematic example of a mounted light emitting component 105 having reflective coating 50, within a housing 106 containing a phosphor, such as a phosphor layer 120. Example light emissions and reflections are depicted, with primary photons 122, emitted from light emitting component 105, stimulated secondary photons emitted from phosphor layer 120, and reflected primary/secondary photons 126 that be reflected off of phosphor layer 120, or another surface, such that they are directed along a path that would hit a sidewall of Silicon substrate 15. Reflective coating 50 reflects such photons so that these photons are not absorbed by Silicon substrate 15. Further description relating to example phosphor combinations and dispositions relative to one or more light emitting components is provided below.

FIG. 24 depicts another example light emitting component where Silicon substrate 15 is shielded from being able to absorb photons in sidewalls by reflective coating 50. FIG. 23 depicts an example where a conducting submount 160 serves as a current path into an active region (not separately identified) through via(s) 161.

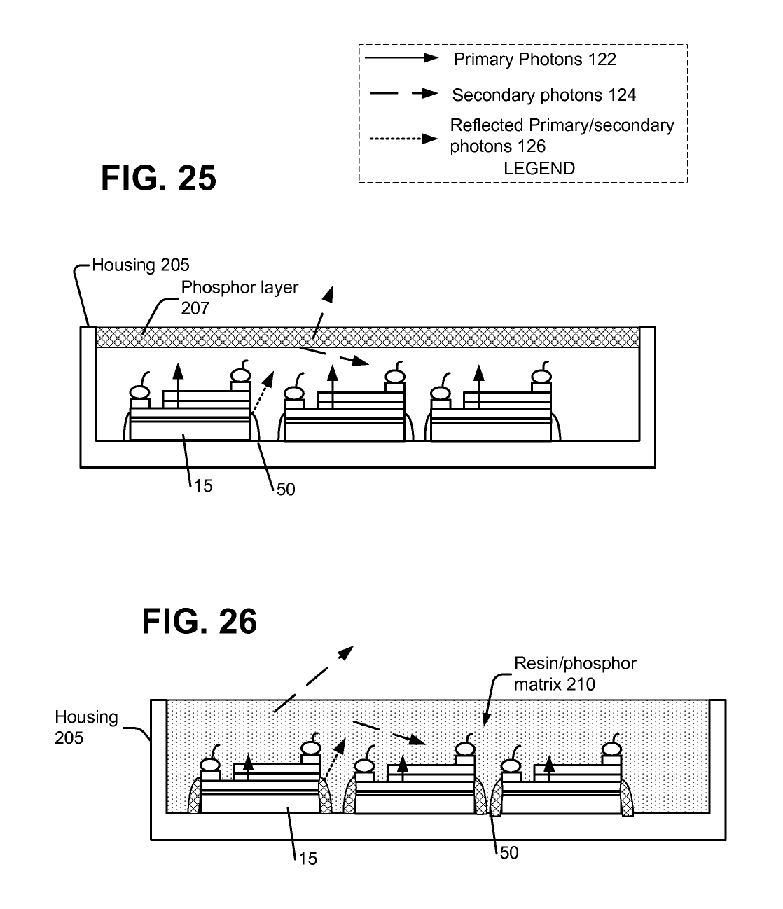

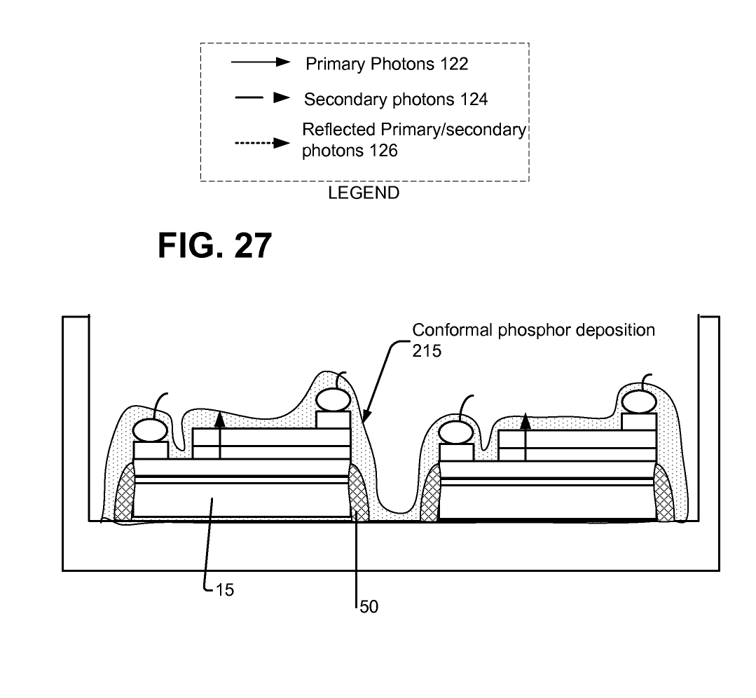

FIG. 25 depicts a further example of packaging where an array of LEDs is provided in a housing 205, with a phosphor layer 207 disposed over the depicted light emitting components. FIG. 26 depicts a further example where a resin/phosphor matrix 210 can be used to fill housing 205. As discussed with some previous examples, the light emitting components of FIGS. 26 and 27 have Silicon substrates with sidewalls coated by reflecting material 50.

FIG. 27 depicts an example of a light emitting components covered in a conformal phosphor deposition 215.

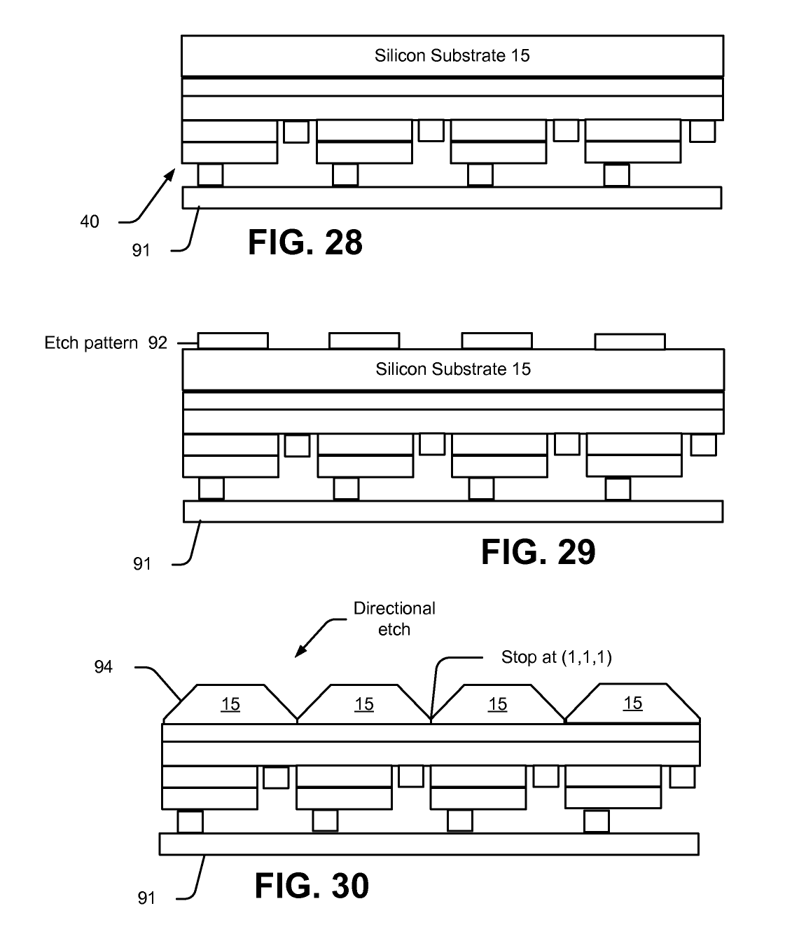

FIGS. 28-33 depict a further example relating to coating substrate 15 prior to singulation, as was introduced with respect to FIGS. 16-20. FIG. 28 depicts a cross section of a silicon substrate 15 (see wafer 35 of FIG. 7) having LED devices (e.g., device 40) formed thereon and mounted to a stretching tape 91(an example of carrier 75 of FIG. 16). Referencing the example devices of FIG. 8 and FIG. 9, each LED device has a variety of constituent components. FIG. 29 depicts that an etch pattern mask 92 is disposed on the exposed surface of silicon substrate 15. FIG. 30 depicts that a directional wet etch is conducted, which stops when exposing a (111) crystal plane of the silicon substrate 15. The directional wet etch causes angled sidewalls (e.g., sidewall 94) to be formed in Silicon substrate 15. Although these figures depict a cross-section, it would be understood that the angle pattern extends on the plane of substrate 15, such that the angled substrate sidewalls circumscribe the depicted LED devices. The use of a wet etch to form the angled sidewalls is an example implementation of a process for making such angled sidewalls. Another example approach is to use angled cuts, such as saw cuts, to define the angled sidewalls. Combinations of different processes, such as cutting and etching, also can be used.

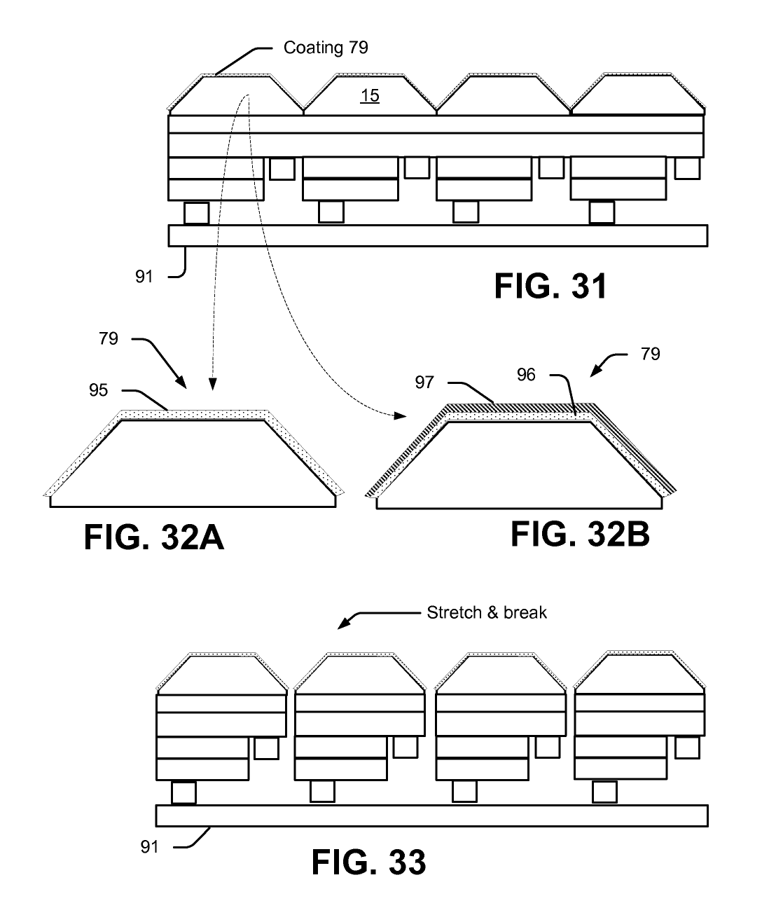

FIG. 31 depicts that the mask portions are removed, and a coating disposed on the processed surface of the Silicon substrate 15. FIG. 32A depicts that the coating can include an insulating reflective coating 95; FIG. 32B depicts that the coating can include an insulating coating 96, and a reflective metal layer 97 on the insulating coating. In FIG. 32B, insulator 96 does not also need to serve as a reflector, due to the reflective metal 83 disposed thereon. Although FIG. 32A depicts an example of an insulating reflective coating, and FIG. 32b depicts an example of a reflective metal coating over an insulator, a still further example is a reflective conducting material (e.g., a metal) that is in electrical conductivity with substrate 15, rather than being insulated therefrom.

FIG. 33 depicts that tape 91 can be stretched so as to singulate along the weakened parts of substrate 15, with the now-formed coating on the angled sidewalls.

In general, the above process flow is exemplary and a variety of other processing steps, or substituted processing steps may be provided in particular implementations. For example, instead of stretching, cutting techniques may be employed; cutting can be performed by UV light, lasers, or by mechanical means. In some situations, a plurality of singulation techniques may be used. The use of angled substrate sidewalls may aid in forming a more-conformal deposition for the reflective layer or layers (reflective oxide or oxide and reflective metal). Using a wet etch also helps prepare the Silicon substrate for receiving the coatings. The directional nature of the etch provides an opportunity to adjust a depth of the etch by adjusting the extent of the mask; e.g., masks that cover more of substrate 15 would leave a thicker wafer to be broken during stretching.

It was discussed that the etch mask was removed in the above-example. However, depending on the nature of the etch mask used, the etch mask may be left in place, and insulator 82 or 84 disposed over the top thereof.

Constituent components of exemplary light emitting components and assemblies thereof include reflective materials used to form reflective coatings on sidewalls of Silicon substrates. In some examples, these reflective coatings are diffusely reflective. The reflective coatings are opaque in the wavelengths of light emitted by the light emitting component and the phosphors used.

For example, reflective coatings can be applied using a coating, such as a conformal coating, of a paste or resin matrix containing an Oxide of Titanium.

Although any highly reflective material with diffuse reflection satisfying the disclosed parameters may be used, examples of reflective materials that can be used include Titanium oxide or other oxide phases or compositions such as Titanium dioxide and trioxides. Diffusive reflectivity is provided by random orientation of the crystals. Other types of particles providing diffuse reflectivity can be provided instead or in addition to those disclosed above.

As would be understood from the above disclosure, different methods may be used for applying layer 106 to sidewalls of Silicon substrates. In general, application methods include spraying, brushing, and screen printing, for example. A suitable compound for spraying includes a Titanium dioxide paste composition comprising polymer matrix, Titanium dioxide filler, and additional rheological additives which adjust rheological properties of the paste. The additional rheological additives comprise, e.g., silica, alumna, zinc oxide, magnesium oxide, talc, and other additives known to a person skilled in the art, used either individually or in combination. The constituent components, e.g., choice of polymer, particle sizes, loading level and the like, can adjusted so that the rheology of the paste follows pseudo-plastic behavior but adheres to the sidewalls without excessive slumping or sloughing.

In one aspect, the polymer matrix may comprise any curable Silicone ensuring a good bond of the Titanium dioxide paste with the surface of a Silicon substrate. Example polymers possessing hydride, hydroxyl or other reactive functionalities can be selected for their superior bonding characteristics. The Titanium dioxide filler may comprise particles with average size between 100 nm to 20 microns, and the loading level may be between 10% to 75%, depending on specific surface area of the Titanium dioxide particles. The particle sizes and loading levels of the rheological additives are selected to adjust rheological properties as disclosed above.

Substrates having such a coating applied can be cured according to a curing process. A curing process can include using an oven at a relatively low temperature, such as 110 degrees Celsius for an appropriate length of time, such as 1-2 hours, followed by a somewhat higher temperature, such as 150 Celsius, baking interval. Further baking intervals can occur, as may be appropriate for specific characteristics of the coating and the chips being processed.

With respect to the phosphors, an example phosphor that can be used is Yttrium-Aluminum-Garnet fluorescent material activated with Cerium (YAG fluorescent material) (YAG:Ce). YAG:Ce has garnet structure. YAG:Ce is stimulated by blue and/or UV light, such as light near 450 nm and 460 nm. YAG:Ce can be tuned to emit different light wavelengths, ranging from green through red, such as 540 nm, 600 nm, or even wavelengths over 700 nm.

A wavelength of emitted light from the light emitting device can be shifted to a shorter wavelength by substituting GA for a portion of Al in the YAG:Ce garnet structure. A wavelength of the emitted light can be shifted towards a longer wavelength by substituting Gd or La for part of Y in the YAG:Ce composition. Limits on Al/Ga and Y/(Gd or La) ratios are controlled based on considerations of light emitting efficiency, where lower Gd or La content means decrease of red wavelength output from the phosphor composition, and relatively high Gd or La substitution increases red output at the expense of luminance. A Lutetium Aluminum phosphor activated with Cerium, but not having a Garnet structure also may be used. Peak energy output ranges for constituent phosphor components can be between 530 nm and 580 nm, for example, in order to combine with peak primary emission in the blue light spectrum. A component of longer wavelength light, such as above 600 nm, or 650 nm can be added in order to bring down a color temperature of the combined light by adding reddish hues.

Multiple different constituent phosphors can be mixed together to form a phosphor used according to the disclosure. Different constituent phosphors can be applied in layers or inhomogeneous combination.

Phosphor material can be mixed into a resin or other carrier matrix, which can be used to pot, coat, or be layered onto light emitting diodes, lenses, components of a package of a light emitting component or an array of such components.

The various aspects illustrated in the drawings may not be drawn to scale. Rather, the dimensions of the various features may be expanded or reduced for clarity. In addition, some of the drawings may be simplified for clarity. Thus, the drawings may not depict all of the components of a given apparatus (e.g., device) or method.

Various aspects are described with reference to drawings that are schematic illustrations and conceptual in nature. As such, variations and differences from the depicted shapes, relative orientations and dimensions, for example, for or as a result of manufacturing techniques, tolerances and so on, are to be expected. Thus, various aspects presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended as limitations concerning implementations of these structures.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower”, can therefore, encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can, therefore, encompass both an orientation of above and below.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, steps, operations, elements, components, and/or groups thereof. The term “and/or” includes any and all combinations of one or more of the associated listed items.

I claim:

1. A light emitting device, comprising:
a light emitting component comprising a Silicon substrate, the Silicon substrate including a top surface, a bottom surface and side walls;
a light reflecting layer formed on at least a portion of the side walls of the Silicon substrate;
a phosphor formed over at least a portion of the light emitting component, wherein the phosphor is capable of:
absorbing a part of light emitted by the light emitting component,
emitting light of a wavelength different from that of the absorbed light,
reflecting a part of the light emitted by the light emitting component; and
wherein the light reflecting layer prevents one or more of a portion of the light emitted by the light emitting component and reflected by the phosphor, and a portion of the light emitted by the phosphor from being absorbed by the portion of the side walls of the substrate covered by the light reflecting layer.

2. The light emitting device of claim 1, wherein the sidewalls of the Silicon substrate are angled, with respect to one or more of the top surface and the bottom surface.

3. The light emitting device of claim 1, wherein the light reflecting layer is opaque in the visible light spectrum.

4. The light emitting device of claim 1, wherein the light reflecting layer comprises a metallic layer.

5. The light emitting device of claim 1, wherein the light reflecting layer comprises an insulating layer and a metallic layer formed on the insulating layer.

6. The light emitting device of claim 1, wherein the light reflecting layer comprises Silicone and an oxide of Titanium.

7. The light emitting device of claim 1, wherein the light reflecting layer covers all the side walls of the Silicon substrate.

8. The light emitting device of claim 1 further comprising a holder, wherein the light emitting device is mounted on the holder and the light reflecting layer is formed on all the side walls of the Silicon substrate but not on the holder.

9. The light emitting device of claim 1 further comprising a holder, wherein the light emitting device is mounted on the holder and the light reflecting layer is formed 1) on all the side walls of the Silicon substrate and 2) on a portion of the holder.

10. The light emitting device of claim 1, wherein the light emitting component is formed on the Silicon substrate.

11. The light emitting device of claim 1, wherein the light emitting component is attached to the Silicon substrate.

12. The light emitting device of claim 1, wherein the light emitting component comprises a Nitride compound semiconductor having constituent components represented by the formula: InᵢGaⱼAlₖN where 0≦i, 0≦j, 0≦k and i+j+k=1.

13. The light emitting device of claim 10 wherein the phosphor contains a garnet fluorescent material comprising 1) at least one element selected from the group consisting of Y, Lu, Se, La, Gd and Sm, and 2) at least one element selected from the group consisting of Al, Ga and In, and being activated with Cerium.

14. The light emitting device of claim 1, wherein the phosphor is a mixture of a plurality of different phosphors, including a garnet fluorescent material capable of emitting light having a peak energy output within a range of 530 nm and 580 nm and a second phosphor capable of emitting red light.

15. The light emitting device of claim 1, wherein the phosphor is a mixture of a plurality of different phosphors, the mixture selected to produce a predetermined color of combined light from the light emitting component and the phosphor.

16. The light emitting device of claim 1, wherein the phosphor comprises one or more of a Yttrium Aluminum Garnet phosphor and a Lutetium Aluminum Garnet phosphor.

17. The light emitting device of claim 1, wherein the light emitting component emits light having peak energy between 420 nm and 490 nm.

18. A method of fabricating a light emitting device, comprising:
forming a light emitting component on a first surface of a Silicon substrate, the Silicon substrate comprising a second surface and side walls defining an extent of the first and second surfaces;
forming a phosphor over at least a portion of the light emitting component, wherein the phosphor is capable of:
absorbing a part of light emitted by the light emitting component,
emitting light of wavelength different from that of the absorbed light,
reflecting a part of the emitted light by the light emitting component; and
forming a light reflecting layer on at least a portion of the side walls of the Silicon substrate, the light reflecting layer preventing at least 1) a portion of the light emitted by the light emitting component and reflected by the phosphor, and 2) a portion of the light emitted by the phosphor, from being absorbed by the portion of the side walls of the substrate covered by the light reflecting layer.

19. The method of claim 18, wherein forming a light emitting component comprises disposing a wafer having formed thereon a plurality of light emitting components on a carrier, and singulating the light emitting components, after the forming of the light reflecting layer.

20. The method of claim 19, wherein singulating the light emitting components, comprises performed a masked wet etch on the Silicon substrate to form angled sidewalls of the light emitting components.

21. The method of claim 20, wherein the singulating is completed by stretching the carrier to break the wafer along edges defined by intersections of the angled sidewalls of the light emitting components.

22. The method of claim 20, wherein the forming of the light reflecting layer comprises depositing a reflective material on the angled sidewalls of the light emitting components.

23. The method of claim 22, wherein the depositing of the reflective insulating material comprises depositing the reflective material on the entirety of either the first or the second surface silicon substrate.

24. The method of claim 22, wherein the depositing of the reflective material comprises depositing a layer of insulator and a layer of metallic material on the layer of insulator.

25. The method of claim 18, wherein forming the light reflecting layer comprises forming an opaque layer.

26. The method of claim 18, wherein forming the light reflecting layer comprises forming a metallic layer.

27. The method of claim 18, wherein forming the light reflecting layer comprises forming a layer comprising Silicone and TiO₂.

28. The method of claim 18, wherein forming the light reflecting layer comprises covering all the side walls of the Silicon substrate.

29. The method of claim 18, further comprising mounting the light emitting device to a holder, wherein the light reflecting layer is formed on all the side walls of the substrate but not on the holder.

30. The method of claim 18, wherein forming the phosphor further comprises forming a garnet fluorescent material comprising 1) at least one element selected from the group consisting of Y, Lu, Se, La, Gd and Sm, and 2) at least one element selected from the group consisting of Al, Ga and In, and being activated with Cerium.

31. The method of claim 18, wherein forming the phosphor further comprises forming a garnet fluorescent material comprising 1) at least one element selected from the group consisting of Y, Lu, Se, La, Gd and Sm, and 2) at least one element selected from the group consisting of Al, Ga and In, and being activated with Cerium.

32. A method of fabricating a light emitting device, comprising:
providing a light emitting component;
attaching the light emitting component to a Silicon substrate, the Silicon substrate comprising a top surface, a bottom surface and side walls;
forming a light reflecting layer on at least a portion of the side walls of the Silicon substrate;
forming a phosphor over at least a portion of the light emitting component, wherein the phosphor is capable of:
absorbing a part of light emitted by the light emitting component,
emitting light of wavelength different from that of the absorbed light,
reflecting a part of the emitted light by the light emitting component; and
wherein the light reflecting layer prevents 1) a portion of the light emitted by the light emitting component and reflected by the phosphor, and 2) a portion of the light emitted by the phosphor, from being absorbed by the portion of the side walls of the substrate covered by the light reflecting layer.

33. The method of claim 32, wherein forming the light reflecting layer comprises forming a layer comprising Silicone and TiO₂.

34. The method of claim 32, wherein forming the light reflecting layer comprises covering all the side walls with a metal.

35. The method of claim 32, wherein forming the light reflecting layer comprises covering all the side walls of the Silicon substrate.

36. The method of claim 32, further comprising mounting the light emitting device to a holder, wherein the light reflecting layer is formed on all the side walls of the substrate but not on the holder.

37. The method of claim 32, further comprising mounting the light emitting device to a holder, wherein the light reflecting layer is formed 1) on all the side walls of the substrate and 2) on a portion of the holder.

38. The method of claim 32, further comprising forming the light emitting component on a second Silicon substrate.

39. The method of claim 32, wherein forming the phosphor further comprises forming a garnet fluorescent material comprising 1) at least one element selected from the group consisting of Y, Lu, Se, La, Gd and Sm, and 2) at least one element selected from the group consisting of Al, Ga and In, and being activated with Cerium.

40. The method of claim 32, wherein forming the phosphor further comprises forming a garnet fluorescent material comprising 1) at least one element selected from the group consisting of Y, Lu, Se, La, Gd and Sm, and 2) at least one element selected from the group consisting of Al, Ga and In, and being activated with Cerium.
